(19) United States
(12) Patent Application Publication
(10) Pub. No.: US 2006/0046506 A1
(43) Pub. Date: Mar. 2, 2006

(54) Soft de-chucking sequence

(75) Inventor: Noriaki Fukiage, Hartsdale, NY (US)

Correspondence Address: PILLSBURY WINTHROP SHAW PITTMAN, LLP, P.O. BOX 10500, MCLEAN, VA, 22102, US

(73) Assignee: Tokyo Electron Limited, Tokyo (JP)

(21) Appl. No.: 10/931,272

(22) Filed: Sep. 1, 2004

(51) Int. Cl. H01L 21/31

(52) U.S. Cl. 438/758

(57) ABSTRACT

A method and apparatus for improving the properties of a deposited film. The method includes depositing a low-k dielectric on a substrate using a plasma-enhanced chemical vapor deposition process and performing a soft de-chucking sequence after depositing the low-k dielectric film using a soft plasma process. The apparatus includes a chamber having an upper electrode coupled to a first RF source and a substrate holder coupled to a second RF source; and a showerhead for providing multiple precursors and process gasses.

### CROSS-REFERENCE TO RELATED APPLICATIONS

This application is related to co-pending U.S. patent application Ser. No. 10/644,958, entitled “Method and Apparatus For Depositing Materials With Tunable Optical Properties And Etching Characteristics”, filed on Aug. 21, 2003; co-pending U.S. patent application Ser. No. 10/702,048, entitled “Method for Depositing Materials on a Substrate”, filed on Nov. 6, 2003; and co-pending U.S. patent application Ser. No. 10/702,043, entitled “Method of Improving Post-Develop Photoresist Profile on a Deposited Dielectric Film”, filed on Nov. 6, 2003. The entire contents of these applications are incorporated herein by reference in their entireties.

### FIELD OF THE INVENTION

The invention relates to using a plasma-enhanced chemical vapor deposition (PECVD) system to deposit a thin film, and more particularly to a method for improving the film properties.

### BACKGROUND OF THE INVENTION

Integrated circuit and device fabrication requires deposition of electronic materials on substrates. Material deposition is often accomplished by plasma-enhanced chemical vapor deposition (PECVD), wherein a substrate (wafer) is placed in a reaction chamber and exposed to an ambient of reactive gases. The gases react on the wafer surface to form the film. The deposited film may be a permanent part of the substrate or a finished circuit. In the case of the finished circuit, the film characteristics are chosen to provide the electrical, physical, and/or chemical properties required for circuit operation. In other cases, the film may be employed as a temporary layer that enables or simplifies device or circuit fabrication.

After the deposition process, one or more post-processing steps can be performed that can affect the quality of the deposited film. One potentially harmful post-processing step is the de-chucking step.

### SUMMARY OF THE INVENTION

One embodiment of the invention relates to a deposition process in a PECVD system, and more particularly, to the deposition of a low-k dielectric with improved properties. More specifically, a soft de-chucking sequence is performed after the deposition process to prevent the degradation of the film properties.

In other embodiments, a soft de-chucking sequence can be performed after a chemical vapor deposition (CVD) process, an etching process, or a sputtering process.

Other aspects of the invention will be made apparent from the description that follows and the drawings appended hereto.

### BRIEF DESCRIPTION OF THE DRAWINGS

In the drawings:

FIG. 1 illustrates a simplified block diagram for a PECVD system in accordance with an embodiment of the invention;

FIG. 2 shows a simplified flow diagram of a procedure for depositing a layer and performing a soft de-chucking sequence in accordance with an embodiment of the invention;

FIG. 3 shows an exemplary set of processes used in a procedure for depositing a layer on a substrate in accordance with an embodiment of the invention;

FIGS. 4A and 4B show exemplary results for a deposition process in accordance with an embodiment of the invention;

FIG. 5 is a table comparing the electrical properties of a low-k dielectric film between a de-chucking sequence A and a soft de-chucking sequence; and

FIGS. 6A and 6B shows another example of a soft de-chucking sequence with multiple SiC films deposited with multiple de-chucking sequences in accordance with an embodiment of the invention.

### DETAILED DESCRIPTION OF AN EMBODIMENT

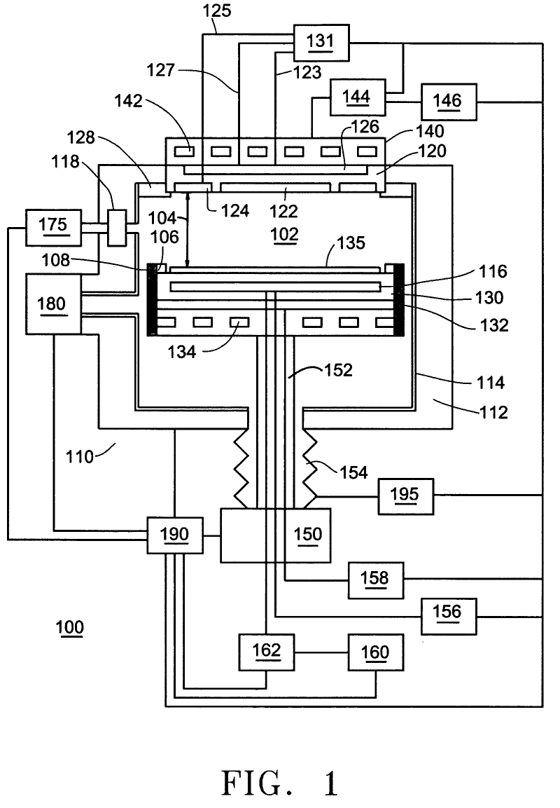

FIG. 1 illustrates a simplified block diagram for a PECVD system in accordance with an embodiment of the invention. In the illustrated embodiment, the PECVD system 100 comprises a processing chamber 110, an upper electrode 140 as part of a capacitively coupled plasma source, a showerhead assembly 120, a substrate holder 130 for supporting a substrate 135, a pressure control system 180, and a controller 190.

In one embodiment, the PECVD system 100 can comprise a remote plasma system 175 that can be coupled to the processing chamber 110 using a valve 118. In another embodiment, the remote plasma system 175 and the valve 118 are not required. In one contemplated variation, the remote plasma system 175 can be used for chamber cleaning.

In one embodiment, the PECVD system 100 can comprise a pressure control system 180 that can be coupled to the processing chamber 110. For example, the pressure control system 180 can comprise a throttle valve (not shown) and a turbomolecular pump (TMP) (not shown) and can provide a controlled pressure in the processing chamber 110. In alternate embodiments, the pressure control system 180 can comprise a dry pump. For example, the chamber pressure can range from approximately 0.1 mTorr to approximately 100 Torr. Alternatively, the chamber pressure can range from approximately 0.1 Torr to approximately 20 Torr.

The processing chamber 110 can facilitate the formation of plasma in a process space 102. The PECVD system 100 can be configured to process substrates of any size, such as 200 mm substrates, 300 mm substrates, or larger substrates. Alternately, the PECVD system 100 can operate by generating plasma in one or more processing chambers.

The PECVD system 100 comprises the showerhead assembly 120 coupled to the processing chamber 110. The showerhead assembly 120 is mounted opposite to the substrate holder 130. The showerhead assembly 120 has a center region 122, an edge region 124, and a sub region 126. A shield ring 128 can be Used to couple the showerhead assembly 120 to the processing chamber 110.

The center region 122 is coupled to a gas supply system 131 by a first process gas line 123. The edge region 124 is coupled to the gas supply system 131 by a second process gas line 125. The sub region 126 is coupled to the gas supply system 131 by a third process gas line 127.

The gas supply system 131 provides a first process gas to the center region 122, a second process gas to the edge region 124, and a third process gas to the sub region 126. The gas chemistries and flow rates can be individually controlled to these regions. Alternately, the center region 122 and the edge region 124 can be coupled together as a single primary region, and the gas supply system 131 can provide the first process gas and/or the second process gas to the primary region. In alternate embodiments, any of the regions can be coupled together and the gas supply system 131 can provide one or more process gasses as appropriate to the selected ones of the regions.

The gas supply system 131 can comprise at least one vaporizer (not shown) for providing precursors. Alternately, a vaporizer is not required. In an alternate embodiment, a bubbling system can be used.

The PECVD system 100 comprises an upper electrode 140 that can be coupled to the showerhead assembly 120 and to the processing chamber 110. The upper electrode 140 can comprise temperature control elements 142. The upper electrode 140 can be coupled to a first RF source 146 using a first match network 144. As would be appreciated by those skilled in the art, it is not necessary for the first match network 144 to be a component separate from the first RF source 146. The two components may be combined without departing from the scope of the present invention.

The first RF source 146 provides a TRF signal to the upper electrode 140, and the first RF source 146 can operate in a frequency range from approximately 0.1 MHz. to approximately 200 MHz. The TRF signal can be in the frequency range from approximately 1 MHz. to approximately 100 MHz., or alternatively in the frequency range from approximately 2 MHz. to approximately 60 MHz. The first RF source 146 can operate in a power range from approximately 0 watts to approximately 10000 watts, or alternatively the first RF source 146 can operate in a power range from approximately 0 watts to approximately 5000 watts.

The upper electrode 140 and the RF source 146 are parts of a capacitively-coupled plasma source. The capacitively-coupled plasma source may be replaced with or augmented by other types of plasma sources, such as an inductively-coupled plasma (ICP) source, a transformer-coupled plasma (TCP) source, a microwave-powered plasma source, an electron cyclotron resonance (ECR) plasma source, a Helicon wave plasma source, and a surface wave plasma source. As is well known in the art, the upper electrode 140 may be eliminated altogether or may be reconfigured for the various suitable plasma sources.

The substrate 135 can be, for example, transferred into and out of the processing chamber 110 through a slot valve (not shown) and chamber feed-through (not shown) via a robotic substrate transfer system (not shown). The substrate 135 can be received by the substrate holder 130 and mechanically translated by devices coupled thereto. Once the substrate 135 is received from the substrate transfer system, the substrate 135 can be raised and/or lowered using a translation device 150 that can be coupled to the substrate holder 130 by a coupling assembly 152.

The substrate 135 can be affixed to the substrate holder 130 via an electrostatic clamping system. For example, an electrostatic clamping system can comprise an electrode 116 and an electrostatic chuck (ESC) supply 156. Clamping voltages that can range from approximately −2000 V to approximately +2000 V, for example, can be provided to the clamping electrode 116. Alternatively, the clamping voltage can range from approximately −1000 V to approximately +1000 V. In alternate embodiments, an ESC system and the ESC supply are not required.

The substrate holder 130 can comprise lift pins (not shown) for lowering and/or raising the substrate 135 to and/or from the surface of the substrate holder 130. In alternate embodiments, different lifting devices can be provided in the substrate holder 130. In alternate embodiments, gas can, for example, be delivered to the backside of the substrate 135 via a backside gas system to improve the gas-gap thermal conductance between the substrate 135 and the substrate holder 130.

A temperature control system can also be provided. Such a system can be utilized when temperature control of the substrate 135 is required at elevated or reduced temperatures. For example, a heating element 132, such as resistive heating elements, or thermoelectric heaters/coolers can be included, and the substrate holder 130 can further include a heat exchange system 134. The heating element 132 can be coupled to a heater supply 158. The heat exchange system 134 can include a re-circulating coolant flow means that receives heat from the substrate holder 130 and transfers heat to a heat exchanger system (not shown), or when heating, transfers heat from the heat exchanger system.

Also, the electrode 116 can be coupled to a second RF source 160 using a second match network 162. It is not necessary for a second match network 162 to be a separate component from the second RF source 160. The two components may be combined without departing from the scope of the present invention.

The second RF source 160 provides a bottom RF signal (BRF) to the lower electrode 116 and can operate in a frequency range from approximately 0.1 MHz. to approximately 200 MHz. The BRF signal can be in the frequency range from approximately 0.2 MHz. to approximately 30 MHz., or alternatively, in the frequency range from approximately 0.3 MHz. to approximately 15 MHz. The second RF source 160 can operate in a power range from approximately 0.0 watts to approximately 1000 watts, or alternatively, the second RF source 160 can operate in a power range from approximately 0.0 watts to approximately 500 watts. In various embodiments, the lower electrode 116 may not be used, or may be the sole source of plasma within the chamber 110, or may augment any additional plasma source.

The PECVD system 100 can further comprise the translation device 150 that can be coupled by a bellows 154 to the processing chamber 110. Also, the coupling assembly 152 can couple the translation device 150 to the substrate holder 130. The bellows 154 is configured to seal the vertical translation device 150 from the atmosphere outside the processing chamber 110.

The translation device 150 allows a variable gap 104 to be established between the showerhead assembly 120 and the substrate 135. The gap 104 can range from approximately 1 mm to approximately 200 mm, and alternatively, the gap 104 can range from approximately 2 mm to approximately 80 mm. The gap 104 can remain fixed or the gap 104 can be changed during a deposition process.

Additionally, the substrate holder 130 can further comprise a focus ring 106 and a ceramic cover 108. Alternately, the focus ring 106 and/or the ceramic cover 108 are not required to practice the present invention.

At least one chamber wall 112 can comprise a coating 114 to protect the wall 112. For example, the coating 114 can comprise a ceramic material. In an alternate embodiment, the coating 114 is not required and may be omitted. Furthermore, a ceramic shield (not shown) can be used within the processing chamber 110. In addition, the temperature control system can be used to control the chamber wall temperature. For example, ports can be provided in the chamber wall 112 for controlling temperature. Chamber wall temperature can be maintained relatively constant while a process is being performed in the chamber 110.

Also, the temperature control system can be used to control the temperature of the upper electrode 116. The temperature control elements 142 can be used to control the upper electrode temperature. Upper electrode temperature can be maintained relatively constant while a process is being performed in the chamber 110.

Furthermore, the PECVD system 100 can also comprise a purging system 195 that can be used for controlling contamination.

In an alternate embodiment, the processing chamber 110 can, for example, further comprise a monitoring port (not shown). A monitoring port can, for example, permit optical monitoring of the process space 102.

The PECVD system 100 also comprises a controller 190. The controller 190 can be coupled to the chamber 110, the showerhead assembly 120, the substrate holder 130, the gas supply system 131, the upper electrode 140, the first RF match network 144, the first RF source 146, the translation device 150, the ESC supply 156, the heater supply 158, the second RF match network 162, the second RF source 160, the purging system 195, the remote plasma device 175, and the pressure control system 180. The controller 190 can be configured to provide control data to these components and receive data such as process data from these components. For example, the controller 190 can comprise a microprocessor, a memory, and a digital I/O port capable of generating control voltages sufficient to communicate and activate inputs to the processing system 100 as well as monitor outputs from the PECVD system 100. Moreover, the controller 190 can exchange information with system components. Also, a program stored in the memory can be utilized to control the aforementioned components of the PECVD system 100 according to a process recipe. In addition, the controller 190 can be configured to analyze the process data, to compare the process data with target process data, and to use the comparison to change a process and/or control the deposition tool. Also, the controller 190 can be configured to analyze the process data, to compare the process data with historical process data, and to use the comparison to predict, prevent, and/or declare a fault.

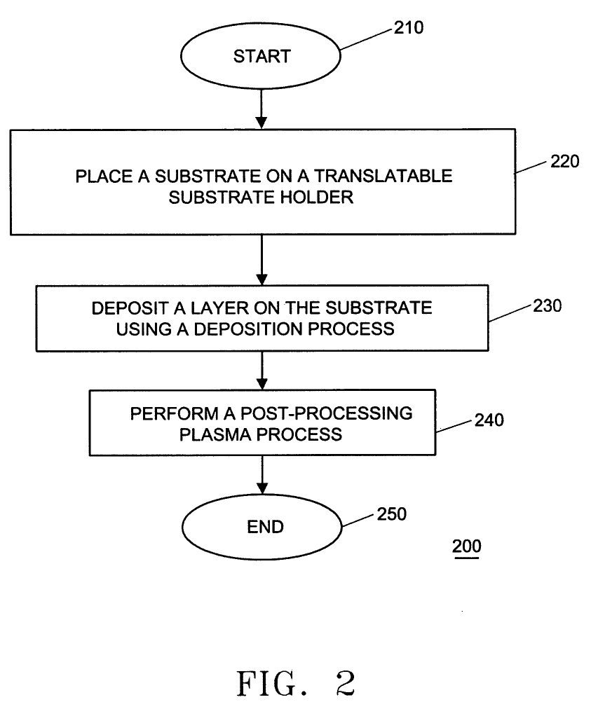

FIG. 2 shows a simplified flow diagram of a procedure for depositing a layer and performing a soft de-chucking sequence in accordance with an embodiment of the invention. In one embodiment, a low-k dielectric layer can be deposited, but this is not required for the invention. In alternate embodiments, other materials may be deposited. Procedure 200 starts at 210.

At 220, the substrate 135 is placed on the substrate holder 130 in the processing chamber 110. For example, the substrate holder 130 can be used to establish the gap 104 between the surface of the upper electrode 140 and a surface of the substrate holder 130. The gap 104 can range from approximately 1 mm to approximately 200 mm, or alternatively, the gap 104 can range from approximately 2 mm to approximately 80 mm. The substrate holder 130 can be translatable. Thus, in alternate embodiments, the gap size can be changed during processing of the wafer.

At 230, one or more layers can be deposited. In one embodiment, a low-k dielectric can be deposited on the substrate 135. In an alternate embodiment, the low-k dielectric may be deposited in one or more layers.

During the low-k dielectric deposition process, a TRF signal can be provided to the upper electrode 140 using the first RF source 146. For example, the first RF source 146 can operate in a frequency range from approximately 0.1 MHz. to approximately 200 MHz. Alternatively, the first RF source 146 can operate in a frequency range from approximately 1 MHz. to approximately 100 MHz., or the first RF source 146 can operate in a frequency range from approximately 2 MHz. to approximately 60 MHz. The first RF source 146 can operate in a power range from approximately 10 watts to approximately 10000 watts, or alternatively, the first RF source 146 can operate in a power range from approximately 10 watts to approximately 5000 watts

Also, during the low-k dielectric deposition process, a BRF signal can be provided to the lower electrode 116 in the substrate holder using the second RF source 160. For example, the second RF source 160 can operate in a frequency range from approximately 0.1 MHz. to approximately 200 MHz. Alternatively, the second RF source 160 can operate in a frequency range from approximately 0.2 MHz. to approximately 30 MHz., or the second RF source 160 can operate in a frequency range from approximately 0.3 MHz. to approximately 15 MHz. The second RF source 160 can operate in a power range from approximately 0.0 watts to approximately 1000 watts, or alternatively, the second RF source 160 can operate in a power range from approximately 0.0 watts to approximately 500 watts. In an alternate embodiment, a BRF signal is not required.

In addition, the showerhead assembly 120 can be provided in the processing chamber 110 and can be coupled to the upper electrode 140. The showerhead assembly 120 can comprise the center region 122, the edge region 124, and the sub region 126, and the showerhead assembly 120 can be coupled to the gas supply system 131. A first process gas can be provided to the center region 122, a second process gas can be provided to the edge region 124 and a third process gas can be provided to the sub region 126 during the deposition process.

Alternately, the center region 122 and the edge region 124 can be coupled together as a single primary region, and gas supply system 131 can provide the first process gas and/or the second process gas to the primary region. In alternate embodiments, any of the regions can be coupled together and the gas supply system can provide one or more process gasses.

The first process gas and the second process gas can comprise at least one of a silicon-containing precursor and a carbon-containing precursor. An inert gas can also be included. For example, the flow rate for the silicon-containing precursor and the-carbon containing precursor can range from approximately 0.0 sccm to approximately 5000 sccm and the flow rate for the inert gas can range from approximately 0.0 sccm to approximately 10000 sccm. The silicon-containing precursor can comprise at least one of monosilane (SiH₄), tetraethylorthosilicate (TEOS), monomethylsilane (1 MS), dimethylsilane (2MS), trimethylsilane (3MS), tetramethylsilane (4MS), dimethyldimethoxysilane (DMDMOS), octamethylcyclotetrasiloxane (OMCTS), and tetramethylcyclotetrasilane (TMCTS). The carbon-containing precursor can comprise at least one of CH₄, C₂H₄, C₂H₂, C₂H₆, C₆H₆ and C₆H₅OH. The inert gas can be at least one of argon, helium, and nitrogen.

In addition, the third process gas can comprise at least one of an oxygen-containing gas, a fluorine-containing gas, and an inert gas. For example, the oxygen-containing gas can comprise at least one of O₂, O₃, CO, NO, N₂O, and CO₂; the fluorine-containing precursor can comprise at least one of CF₄, C₂F₆, C₃F₈, C₄F₈, COF₂, CHF₃, CH₂F₂, CH₃F, SF₆, F₂ and NF₃; and the inert gas can comprise at least one of N₂, Ar, and He. The flow rate for the third process gas can range from approximately 0.0 sccm to approximately 10000 sccm.

The flow rates for the first process gas, the second process gas and third process gas can be independently established during the deposition of the low-k dielectric.

The pressure control system 180 can be coupled to the chamber 110, and the chamber pressure can be controlled using the pressure control system 180. For example, the chamber pressure can range from approximately 0.1 mTorr to approximately 100 Torr.

A temperature control system can be coupled to the substrate holder 130, and the substrate temperature can be controlled using the temperature control system. For example, the substrate temperature can range from approximately 0° C. to approximately 500° C. The temperature control system can also be coupled to a chamber wall 112, and the temperature of the chamber wall 112 can be controlled using the temperature control system. For example, the temperature of the chamber wall 112 can range from approximately 0° C. to approximately 500° C. In addition, the temperature control system can be coupled to the showerhead assembly 120, and the temperature of the showerhead assembly 120 can be controlled using the temperature control system. For example, the temperature of the showerhead assembly 120 can range from approximately 0° C. to approximately 500° C.

At 240, a post-processing plasma process can be performed after the deposition process. By performing a post process plasma treatment including a soft de-chucking sequence, the electrical potential between the substrate 135 and substrate holder 130, which is generated by the plasma process during deposition or other means utilizing plasma, can be removed or at least decreased.

The soft de-chucking sequence can comprise a discharge step in which a post-processing plasma is used. In one embodiment, a soft plasma can be created during the discharge step using a smaller amount of RF power than is used during the deposition process. Alternately, a soft plasma can be created before or after the discharge step. In other embodiments, a discharge step is not required. The discharge step can extend from approximately 1 second to approximately 20 seconds.

During the discharge step, a TRF signal can be provided to the upper electrode 140 using the first RF source 146. For example, the first RF source 146 can operate in a frequency range from approximately 0.1 MHz. to approximately 200 MHz. Alternatively, the first RF source 146 can operate in a frequency range from approximately 1 MHz. to approximately 100 MHz., or the first RF source 146 can operate in a frequency range from approximately 2 MHz. to approximately 60 MHz. The first RF source 146 can operate in a power range from approximately 0.1 watts to approximately 200 watts, or the first RF source 146 can operate in a power range less than approximately 0.6 W/cm².

In addition, a process gas can be provided into the processing chamber 110. For example, the flow rate for the process gas can range from approximately 0.0 sccm to approximately 10000 sccm. The process gas can comprise one or more gasses. In one embodiment, the process gas can comprise an inert gas, and the inert gas can comprise at least one of Ar, He, and N₂. For example, the process gas can comprise He, and the flow rate can vary from approximately 50 sccm to approximately 5000 sccm. The process gas can be provided using a dual zone gas showerhead, and the flow rates can be independently established for the center zone 122 and the edge zone 124.

In alternate embodiments, the process gas may comprise an oxygen-containing gas and/or a hydrogen-containing gas. For example, an oxygen-containing-gas can comprise at least one of NO, N₂O, O₂, O₃, CO, and CO₂, and a hydrogen-containing gas can comprise at least one of H₂O and H₂. The flow rates for the process gas and the inert gas can be independently established during the post-processing sequence.

During the discharge step, an ESC voltage is not required. Alternately, the ESC voltage can be lowered from a clamping potential to a lower potential. For example, the lower potential can be approximately zero volts.

In addition, the soft de-chucking sequence can comprise a pin up step in which a post-processing plasma is also used. In one embodiment, a soft plasma can be created during the discharge step and maintained during the pin up step. Alternately, a soft plasma can be created during the pin up step. In other embodiments, a pin up step is not required. The pin up step can extend from approximately 1 second to approximately 20 seconds. During a pin up step, lift pins can be used to raise the substrate 135 off of the holder 130.

In addition, during the pin up step, a TRF signal can also be provided to the upper electrode 140 using the first RF source 146. For example, the first RF source 146 can operate in a frequency range from approximately 0.1 MHz. to approximately 200 MHz. Alternatively, the first RF source 146 can operate in a frequency range from approximately 1 MHz. to approximately 100 MHz., or the first RF source 146 can operate in a frequency range from approximately 2 MHz. to approximately 60 MHz. The first RF source 146 can operate in a power range from approximately 0.1 watts to approximately 200 watts, or the first RF source 146 can operate in a power range less than approximately 0.6 W/cm².

In addition, a process gas can be provided into the processing chamber 110. For example, the flow rate for the process gas can range from approximately 0.0 sccm to approximately 10000 sccm. The process gas can comprise one or more gasses. In one embodiment, the process gas can comprise an inert gas, and the inert gas can comprise at least one of Ar, He, and N₂. For example, the process gas can comprise He, and the flow rate can vary from approximately 50 sccm to approximately 5000 sccm. The process gas can be provided using a dual zone gas showerhead, and the flow rates can be independently established for the center zone 122 and the edge zone 124.

In alternate embodiments, the process gas may comprise an oxygen-containing gas and/or a hydrogen-containing gas. For example, an oxygen-containing-gas can comprise at least one of NO, N₂O, O₂, O₃, CO, and CO₂, and a hydrogen-containing gas can comprise at least one of H₂O and H₂. The flow rates for the process gas and the inert gas can be independently established during the post-processing sequence.

During the pin up step, an ESC voltage is not required. Alternately, the ESC voltage can be lowered from a clamping potential to a lower potential during the pin up step. For example, the lower potential can be approximately zero volts.

During the soft de-chucking sequence the chamber pressure can remain constant. In addition, the chamber pressure can be changed before and/or after a soft de-chucking sequence. For example, the chamber pressure can vary from approximately 0.1 mTorr to approximately 100 Torr.

During the soft de-chucking sequence the gap 104 can remain constant or can be changed. In addition, the gap 104 can be changed before and/or after the soft de-chucking sequence. For example, the gap 104 can vary from approximately 2 mm to 200 mm.

Procedure 200 ends in 250.

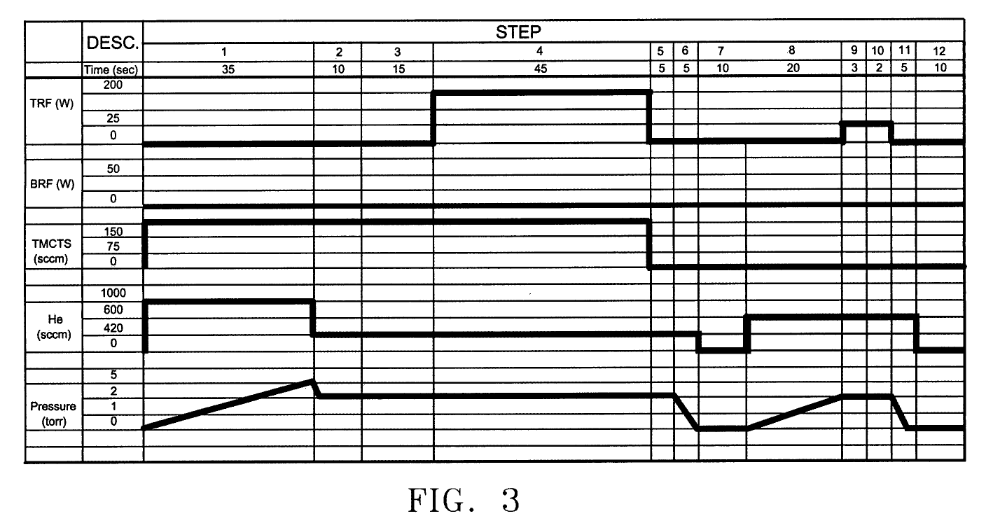

FIG. 3 shows an exemplary set of processes used in a procedure for depositing a layer on the substrate 135 in accordance with an embodiment of the invention. In the illustrated embodiment, a low-k dielectric is deposited. In alternate embodiments, a different set of processes can be used, and different types of layers can be deposited.

In the first step, the processing gases are introduced into the chamber 110, and an operating pressure is established. For example, the chamber pressure can be changed to approximately 5 Torr, and the duration of the first step can be approximately thirty-five seconds. The processing gases can include a precursor that includes silicon, carbon and oxygen, such as TMCTS, and an inert gas. For example, the flow rate for the precursor can be approximately 150 sccm, and the flow rate for the inert gas can be approximately 1000 sccm. In alternate embodiments, different pressures, different flow rates, different gases, different precursors, and different durations can be used.

In the second step, the flow rate for the inert gas and the chamber pressure can be changed. For example, the flow rate for the inert gas can be changed to approximately 420 sccm, and the chamber pressure can be changed to approximately 2 Torr.

In the third step, a stabilization process can be performed. For example, the flow rate of the precursor, the flow rate of the inert gas, and the chamber pressure can be held substantially constant.

In the fourth step, a layer or a portion of a layer can be deposited. For example, a low-k dielectric layer can be deposited. The first RF source 146 can provide an RF signal (TRF) to the upper electrode 140. The TRF frequency can be in the range from approximately 0.1 MHz. to approximately 200 MHz. and the TRF power can be in the range from approximately 10 watts to approximately 10000 watts. For example, the TRF power can be approximately 200 watts.

In an alternate embodiment, a BRF signal can be provided in which the frequency can be in the range from approximately 0.1 MHz. to approximately 200 MHz. and the BRF power can be in the range from approximately 0 watts to approximately 1000 watts.

In the fifth step, the TRF signal level can be altered, the processing gasses can be changed, and flow rates can be modified. In the illustrated embodiment (FIG. 3), the TRF signal was turned off, the precursor flow rate was changed to approximately 0.0 sccm, and the flow rate of the inert gas was held constant.

In the sixth step, the TRF signal can remain off, the chamber pressure can be changed, and flow rate for the inert gas can be kept substantially constant. In the illustrated embodiment (FIG. 3), the chamber pressure was lowered.

In the seventh step, a vacuum process can be performed. For example, the flow rate of the inert gas can be changed, and the chamber pressure can be held low.

In the eighth step, the chamber pressure can be increased, and an inert gas can be provided in the chamber 110. In the illustrated embodiment (FIG. 3), the RF signal is off, the flow rate of the inert gas was set to approximately 600 sccm, and the chamber pressure was increased to approximately 2 Torr.

In the ninth step, a discharge sequence can be performed. In the illustrated embodiment (FIG. 3), the TRF signal was turned on, the flow rate of the silicon-containing precursor gas was set to zero, the flow rate of the inert gas was set to approximately 600 sccm, and the chamber pressure was maintained at approximately 2 Torr.

In the tenth step, a pin up process can be performed. For example, the lift pins can be extended to lift the substrate 135 off the substrate holder 130. Alternately, lift pins can be fixed constant in a position and the substrate holder 130 can be lowered. In addition, an RF signal can be provided during at least a portion of the pin up process.

In the eleventh step, a purging process can be performed. For example, the TRF signal can be altered, and the chamber pressure can be changed. In the illustrated embodiment (FIG. 3), the TRF signal was turned off, the flow rate of the silicon-containing precursor gas was set to zero, the flow rate of the inert gas was set to approximately 600 sccm, and the chamber pressure was decreased from approximately 2 Torr.

In the twelfth step, the chamber 110 is evacuated and the pressure remains low. For example, processing gas is not provided to the chamber during this step.

The above example illustrates that a layer can be deposited by using a PECVD procedure to deposit the layer. During a deposition process, one or more layers can be deposited sequentially in one chamber 110. During the period between layer depositions, the plasma can be turned off. In an alternate embodiment, one or more layers can be deposited sequentially in the same chamber 110 without turning off the plasma. In an alternate embodiment, one or more layers can be deposited in separate chambers.

In this embodiment, the chamber 110 is kept at a specific pressure between the deposition of one or more layers. In an alternate embodiment, the chamber 110 may be evacuated between the deposition of the layers.

The above example illustrates that a low-k dielectric layer can be deposited and a soft plasma de-chucking sequence can be performed to remove the potential between the substrate 135 and the substrate holder 130 and to prevent damage from occurring during the de-chucking sequence.

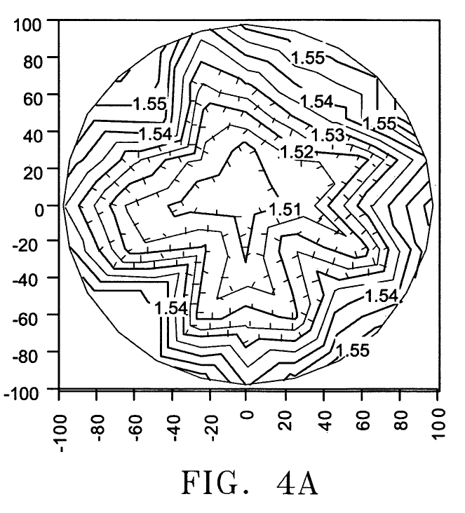

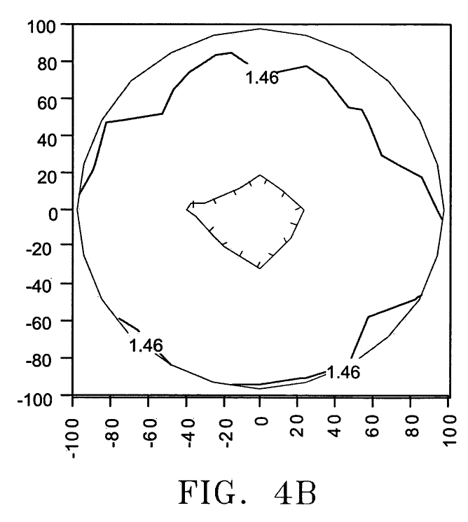

FIGS. 4A and 4B show exemplary results for a deposition process in accordance with an embodiment of the invention. In the illustrated embodiments, wafer maps are shown for a TMCTS deposition process that includes a soft plasma de-chucking sequence. The results show improved uniformity across the wafer. As shown in FIG. 4A, the refractive index (RI),which is applied during another de-chucking sequence A with a TRF of 500 W, a pressure of 0.4 Torr, a discharge time of 5 sec and a pin up time of 2 sec, is approximately 1.535. The refractive index range is approximately 0.0524, and the refractive index uniformity (1 Sigma) is approximately 1.03%. As shown in FIG. 4B, where a soft de-chucking sequence is applied as described in this disclosure, the refractive index (RI) is approximately 1.488, the refractive index range is approximately 0.0093, and the refractive index uniformity (1 Sigma) is approximately 0.15%.

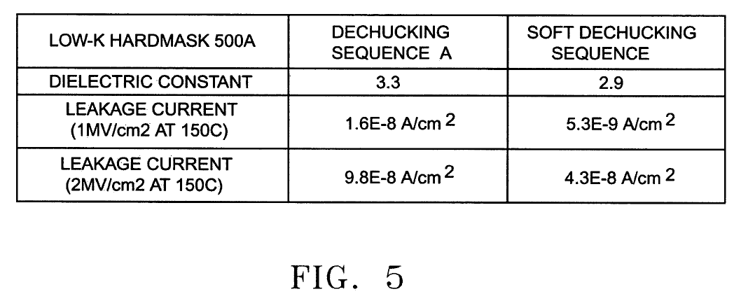

FIG. 5 shows the comparison table of electrical properties of low-k dielectric film between de-chucking sequence A and a soft de-chucking sequence. The soft de-chucking sequence improved the dielectric constant from 3.3 of the de-chucking sequence A down to 2.9 by reducing the damage to the thin film that was generated by de-chucking plasma. In addition, leakage current was improved by the soft de-chucking sequence from 1.6E-8A/cm² down to 5.3E-9A/cm² at 1 MV/cm, and from 9.8E-8A/cm² down to 4.3E-8A/cm² at 2MV/cm.

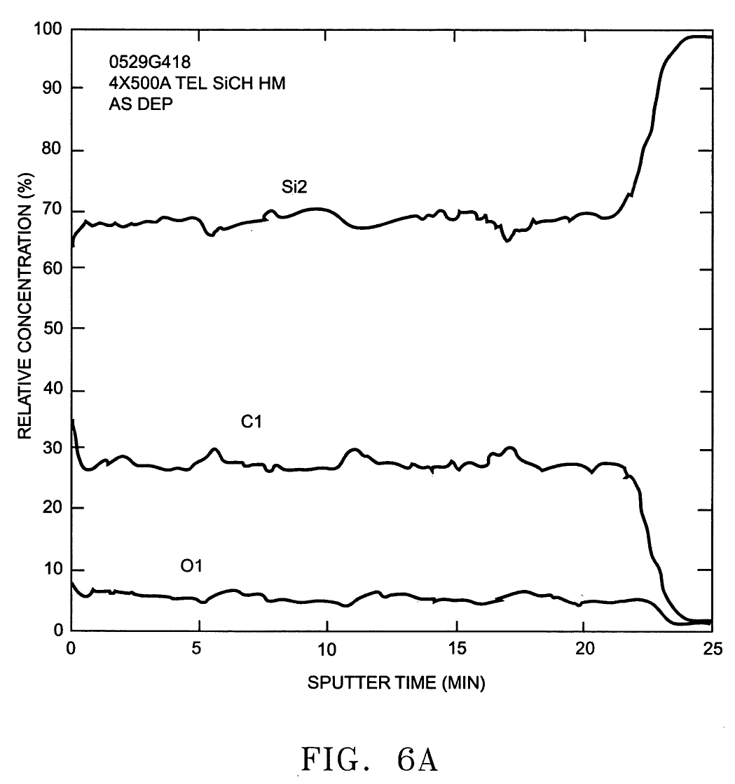

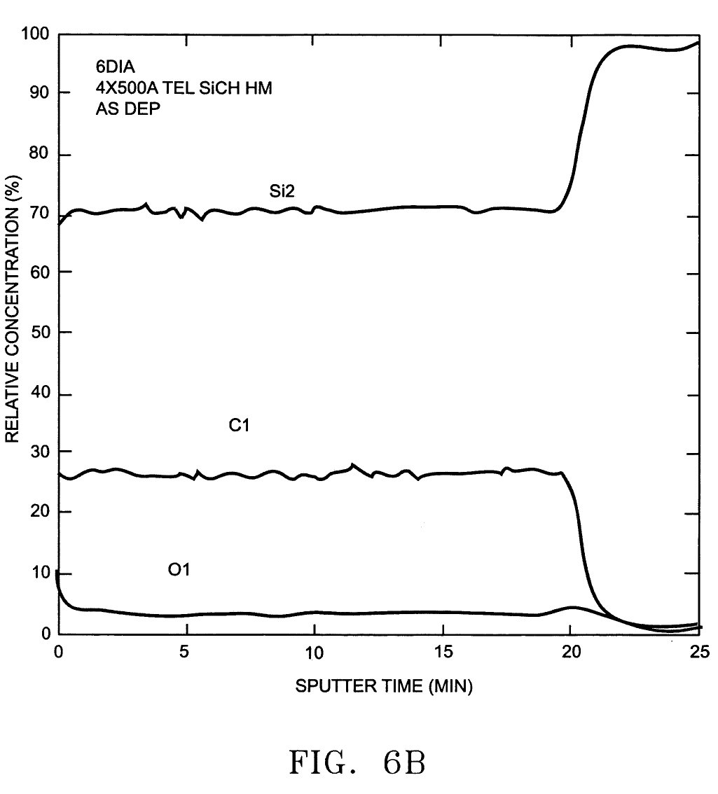

FIGS. 6A and 6B show another example of a soft de-chucking sequence with multiple SiC films deposited with 3MS and He and with a multiple de-chucking sequence. An Auger depth profile is shown in FIGS. 6A and 6B, illustrating a four times deposition of 50 nm thick SiC film including four times de-chucking sequence A. FIG. 6A shows abnormal peaks Si, C and O in the middle of the film stack, which indicates the modification of film structure is due to the de-chucking sequence. In contrast to FIG. 6A with de-chucking sequence A, FIG. 6B, with the soft de-chucking sequence, shows no significant peaks in the structure.

Although only certain exemplary embodiments of this invention have been described in detail above, those skilled in the art will readily appreciate that many modifications are possible in the exemplary embodiments without materially departing from the novel teachings and advantages of this invention. Accordingly, all such modifications are intended to be included within the scope of this invention.

What is claimed is:

1. A method for performing a plasma processing on a substrate, the method comprising:
placing a substrate on a substrate holder in a plasma processing chamber;
performing the plasma process on the substrate; and
performing a soft de-chucking sequence while removing the substrate from the substrate holder.

2. The plasma processing as claimed in claim 1, wherein the plasma processing comprises plasma enhanced chemical vapor deposition (PECVD) plasma processing.

3. The method as claimed in claim 1, further comprising creating a soft plasma using an inert gas during the soft de-chucking sequence.

4. The method as claimed in claim 3, wherein the flow rate of the inert gas is between approximately 0.0 sccm and approximately 10000 sccm.

5. The method as claimed in claim 3, wherein the inert gas comprises Ar, He, or N₂, or a combination of two or more thereof.

6. The method as claimed in claim 3, further comprising creating the soft plasma using an oxygen-containing gas during the soft de-chucking sequence.

7. The method as claimed in claim 6, wherein a flow rate of the oxygen-containing gas is between approximately 0.0 sccm and approximately 10000 sccm.

8. The method as claimed in claim 6, wherein the oxygen-containing gas comprises NO, N₂O, O₂, O₃, CO, or CO₂, or a combination of two or more thereof.

9. The method as claimed in claim 6, further comprising creating the soft plasma using an hydrogen-containing gas during the soft de-chucking sequence.

10. The method as claimed in claim 9, wherein a flow rate of the hydrogen-containing gas is between approximately 0.0 sccm and approximately 10000 sccm.

11. The method as claimed in claim 9, wherein the hydrogen-containing gas comprises H₂O or H₂, or a combination thereof.

12. The method as claimed in claim 3, further comprising creating the soft plasma using an hydrogen-containing gas during the soft de-chucking sequence.

13. The method as claimed in claim 12, wherein a flow rate of the hydrogen-containing gas is between approximately 0.0 sccm and approximately 10000 sccm.

14. The method as claimed in claim 12, wherein the hydrogen-containing gas comprises H₂O or H₂, or a combination thereof.

15. The method as claimed in claim 1, further comprising creating a soft plasma during the soft de-chucking sequence using an RF source coupled to the plasma processing chamber, wherein the RF source operates in a frequency range from approximately 0.1 MHz. to approximately 200 MHz. and in a power range from approximately 0.1 watts to approximately 200 watts.

16. The method as claimed in claim 1, further comprising creating a soft plasma during the soft de-chucking sequence using an RF source coupled to the plasma processing chamber, wherein the RF source operates in a frequency range from approximately 0.1 MHz. to approximately 200 MHz. and in a power range less than 0.6 W/cm².

17. The method as claimed in claim 1, further comprising creating a soft plasma during the soft de-chucking sequence using a pressure control system coupled to the plasma processing chamber, wherein the pressure control system controls chamber pressure in a range from approximately 0.1 mTorr to approximately 100 Torr.

18. The method as claimed in claim 1, further comprising creating a soft plasma during the soft de-chucking sequence at the gap between a showerhead and a substrate holder in the plasma processing chamber, wherein the gap ranges from approximately 2 mm to approximately 200 mm.

19. The method as claimed in claim 1, further comprising creating a soft plasma during the soft de-chucking sequence using a translation device coupled to the plasma processing chamber and the substrate holder, wherein the translation device operates to control a variable gap between a showerhead and the substrate.

20. The method as claimed in claim 1, wherein the soft de-chucking sequence comprises a discharge step, and a soft plasma is created during the discharge step and is extinguished during the discharge step.

21. The method as claimed in claim 1, wherein the soft de-chucking sequence comprises a discharge step, and a soft plasma is created before the discharge step and is extinguished during the discharge step.

22. The method as claimed in claim 1, wherein the soft de-chucking sequence comprises a discharge step, and a soft plasma is created during the discharge step and is extinguished after the discharge step.

23. The method as claimed in claim 1, wherein the soft de-chucking sequence comprises a discharge step, and a soft plasma is created before the discharge step and is extinguished after the discharge step.

24. The method as claimed in claim 1, wherein the soft de-chucking sequence comprises a pin up step, and a soft plasma is created and is extinguished during the pin up step.

25. The method as claimed in claim 1, wherein the soft de-chucking sequence comprises a pin up step, and a soft plasma is created before the pin up step and is extinguished during the pin up step.

26. The method as claimed in claim 1, wherein the soft de-chucking sequence comprises a pin up step, and a soft plasma is created during the pin up step and is extinguished after the pin up step.

27. The method as claimed in claim 1, wherein the soft de-chucking sequence comprises a pin up step, and a soft plasma is created before the pin up step and is extinguished after the pin up step.

28. The method as claimed in claim 1, wherein the soft de-chucking sequence comprises a discharge step and a pin up step, and the soft plasma is created during the discharge step and is extinguished during the pin up step.

29. The method as claimed in claim 1, wherein the soft de-chucking sequence comprises a discharge step and a pin up step, and the soft plasma is created before the discharge step and is extinguished during the pin up step.

30. The method as claimed in claim 1, wherein the soft de-chucking sequence comprises a discharge step and a pin up step, and the soft plasma is created during the discharge step and is extinguished after the pin up step.

31. The method as claimed in claim 1, wherein the soft de-chucking sequence comprises a discharge step and a pin up step, and the soft plasma is created before the discharge step and is extinguished after the pin up step.

32. The method as claimed in claim 1, wherein the soft de-chucking sequence time is between approximately 2 seconds and approximately 180 seconds.

33. The method as claimed in claim 2, further comprising creating a processing plasma during the deposition using an RF source coupled to the PECVD chamber, wherein the RF source operates in a frequency range from approximately 0.1 MHz. to approximately 200 MHz. and in a power range from approximately 10 watts to approximately 10000 watts.

34. The method as claimed in claim 33, further comprising creating the processing plasma during the deposition using a second RF source coupled to the substrate holder, wherein the second RF source operates in a frequency range from approximately 0.1 MHz. to approximately 200 MHz. and in a power range from approximately 0.0 watts to approximately 500 watts.

35. The method as claimed in claim 2, wherein a deposition time is between approximately 5 seconds and approximately 180 seconds.

36. The method as claimed in claim 2, further comprising creating a processing plasma during the deposition using a showerhead assembly coupled to the PECVD chamber, wherein the showerhead assembly provides a process gas during the deposition, wherein the process gas comprises a silicon-containing precursor, a carbon-containing precursor, or an inert gas or a combination of two or more thereof.

37. The method as claimed in claim 36, further comprising flowing the process gas at a first rate between approximately 0.0 sccm to approximately 5000 sccm.

38. The method as claimed in claim 36, wherein the silicon-containing precursor comprises monosilane (SiH₄), tetraethylorthosilicate (TEOS), monomethylsilane (1 MS), dimethylsilane (2MS), trimethylsilane (3MS), tetramethylsilane (4MS), dimethyldimethoxysilane (DMDMOS), octamethylcyclotetrasiloxane (OMCTS), or tetramethylcyclotetrasilane (TMCTS), or a combination of two or more thereof.

39. The method as claimed in claim 36, wherein the carbon-containing precursor comprises CH₄, C₂H₄, C₂H₂, C₆H₆, or C₆H₅OH, or a combination of two or more thereof.

40. The method as claimed in claim 36, wherein the inert gas comprises argon, helium, or nitrogen, or a combination of two or more thereof.

41. The method as claimed in claim 36, further comprising creating the processing plasma during the deposition using a pressure control system coupled to the PECVD chamber, wherein the pressure control system operates to control chamber pressure between approximately 0.1 mTorr and approximately 100 Torr.

42. The method as claimed in claim 36, further comprising creating a soft plasma during the soft de-chucking sequence using an electrostatic chuck (ESC) coupled to the substrate holder, wherein the ESC provides a DC voltage to clamp the substrate to the substrate holder between approximately −2000 V. and approximately +2000 V.

43. The method as claimed in claim 36, wherein, during the deposition, a low-k dielectric layer is deposited.

44. The plasma processing as claimed in claim 1, wherein the plasma processing includes a plasma etching process.

45. The plasma processing as claimed in claim 1, wherein the plasma processing includes a plasma sputtering process.
